(19) United States
(12) Patent Application Publication
(10) Pub. No.: US 2010/0006930 A1
(43) Pub. Date: Jan. 14, 2010

(54) SEMICONDUCTOR DEVICE, MANUFACTURING METHOD THEREOF, AND DATA PROCESSING SYSTEM

(75) Inventor: Noriaki MIKASA, Tokyo (JP)

Correspondence Address: YOUNG & THOMPSON, 209 Madison Street, Suite 500, Alexandria, VA, 22314, US

(73) Assignee: Elpida Memory, Inc., Tokyo (JP)

(21) Appl. No.: 12/496,166

(22) Filed: Jul. 1, 2009

(30) Foreign Application Priority Data
Jul. 10, 2008 (JP) 2008-179979

(51) Int. Cl. H01L 27/06; H01L 21/8234; H01L 29/78

(52) U.S. Cl. 257/332; 257/334; 438/270; 257/E29.262; 257/E21.629; 257/E27.013

(57) ABSTRACT

A semiconductor device manufacturing method includes steps of: etching a semiconductor substrate 2 by using hard masks 71, 72 and 73; forming a sidewall insulating film 38 on side surfaces of these hard masks 71, 72 and 73; selectively removing the sidewall insulating film 38 formed on the side surfaces of the hard masks 71, 72; further etching the semiconductor substrate 2 by using the hard masks 71, 72 and 73 and the sidewall insulating film 38; simultaneously forming gate trenches 12, 22 and 32 at a part of the semiconductor substrate 2 covered by the hard masks 71, 72 and 73; and forming gate electrodes 13, 23 and 33 inside the gate trenches 12, 22 and 32. Accordingly, plural recess channel transistors having different heights of fin-shaped regions 21f, 31f can be formed simultaneously.

### BACKGROUND OF THE INVENTION

1. Field of the Invention

The present invention relates to a semiconductor device and a manufacturing method thereof, and, more particularly relates to a semiconductor device having a recess channel MOS transistor and a method of manufacturing the semiconductor device. The present invention also relates to a data processing system including the semiconductor device.

2. Description of Related Art

Integration of semiconductor devices has so far been achieved mainly by downscaling of transistors. However, when downscaling is progressed, a gate length of a normal planar transistor becomes unavoidably smaller. When the gate length becomes smaller, a sub-threshold current increases due to a short channel effect. To prevent the short channel effect, impurity concentration of a channel region needs to be increased.

However, when the impurity concentration of the channel region is increased, junction leakage increases. While junction leakage does not become a significant problem in a transistor used in a logic circuit, it causes a considerable aggravation of a refresh characteristic of a transistor used for a DRAM (Dynamic Random Access Memory). Consequently, as a method of preventing a short channel effect of DRAM cell transistors in particular, increasing the impurity concentration of the channel region is not appropriate.

Instead of two-dimensionally forming a transistor such as a planar transistor, various techniques of three-dimensionally forming a transistor have been proposed to suppress the short channel effect without increasing the impurity concentration of the channel region.

As one of three-dimensional transistors, a recess channel (trench gate) transistor has been known (see Japanese Patent Application Laid-open Nos. 2005-322880, 2006-173429, and 2006-261627). The recess channel transistor is a type of transistor having a gate electrode embedded into trenches formed on a semiconductor substrate, and source/drain regions are formed at both sides of each trench. When the recess channel transistor is used, an effective gate length increases because an on-current flows three-dimensionally along the trench. Accordingly, the short channel effect can be suppressed while decreasing a planar exclusive area.

However, because of a large channel resistance, the recess channel transistor has a smaller current-driving capacity than that of the planar transistor. Therefore, when a recess channel transistor which is the same as the cell transistor is used for a peripheral circuit, its operation speed falls. Accordingly, the cell transistor needs to be the recess channel type, and the transistor of the peripheral circuit needs to be the planar type. Consequently, it has been difficult to simultaneously form the cell transistor and the transistor of the peripheral circuit in the same process.

Meanwhile, a recess channel transistor having fin-shaped channel regions at both sides of each trench has been also known. Because this type of transistor has a larger current-driving capacity than that of a normal recess transistor, this type of transistor can be also used for a peripheral circuit.

However, the recess channel transistor having the fin-shaped regions has a difficulty of controlling a threshold voltage by ion implantation, and has a problem that the threshold voltage easily becomes low. Therefore, it is not appropriate to use this type of transistor as a cell transistor of a memory cell.

As explained above, because a cell transistor of a memory cell and a transistor of a peripheral circuit are required to have different characteristics respectively, it has been difficult to simultaneously form these transistors in the same process. This problem occurs not only in the relationship between the memory cell and the peripheral circuit, but also within the peripheral circuit. This is because different transistor characteristics are often required depending on a circuit block within the peripheral circuit.

As described above, conventionally, it has been difficult to simultaneously form recess channel transistors having different characteristics in the same process.

### SUMMARY

The present invention seeks to solve one or more of the above problems, or to improve upon those problems at least in part.

In one embodiment, there is provided a semiconductor device comprising a plurality of transistors including at least first and second transistors, wherein each of the transistors includes an active region having a gate trench formed therein, a gate electrode provided along a first direction crossing the active region in which at least a part of the gate electrode is embedded in the gate trench, and a source region and a drain region provided in the active region and arranged side by side in a second direction intersecting with the first direction with intervention of the gate electrode, a depth of the gate trench in a cross section along the first direction in the first transistor is different from a depth of the gate trench in a cross section along the first direction in the second transistor, and a depth of the gate trench in a cross section along the second direction in the first transistor is substantially equal to a depth of the gate trench in a cross section along the second direction in the second transistor.

In another embodiment, there is also provided a semiconductor device that includes a plurality of transistors, at least first and second transistors, wherein each of the transistors includes an active region having a gate trench formed therein, a gate electrode embedded in the gate trench via a gate insulating film and having first and second side surfaces perpendicular to a main surface of a semiconductor substrate and parallel to each other and third and fourth side surfaces perpendicular to a main surface of the semiconductor substrate and parallel to each other and bottom surface parallel to the main surface of the semiconductor substrate, a source region provided in the active region and provided at a position facing the first side surface of the gate electrode via the gate insulating film, a drain region provided in the active region and provided at a position facing the second side surface of the gate electrode via the gate insulating film, a first channel region provided in the active region and provided at a position facing at least the bottom surface of the gate electrode via the gate insulating film, and a second channel region provided in the active region and provided at a position facing the third and fourth side surfaces of the gate electrode via the gate insulating film. Heights of the first and second side surfaces of the gate electrode at a part facing the active region in the first transistor are substantially equal to heights of the first and second side surfaces of the gate electrode at a part facing the active region in the second transistor, and heights of the third and fourth side surfaces of the gate electrode at a part facing the active region in the first transistor are different from heights of the third and fourth side surfaces of the gate electrode at a part facing the active region in the second transistor.

In another embodiment, there is provided a method of manufacturing a semiconductor device comprising: forming first and second hard masks on a semiconductor substrate; etching the semiconductor substrate by using the first and second hard masks; forming a first sidewall insulating film on side surfaces of the first and second hard masks, respectively; selectively removing the first sidewall insulating film formed on the side surface of the first hard mask; etching the semiconductor substrate by using the first and second hard masks and the first sidewall insulating film; removing the first and second hard masks, and thereafter simultaneously forming first and second gate trenches, respectively on a part of the semiconductor substrate at removed portions of the first and second hard masks; forming first and second gate electrodes by embedding a conductive material into the first and second gate trenches; and forming a source region and a drain region on the semiconductor substrate positioned at a mutually different side viewed from the first and second gate electrodes, respectively.

In another embodiment, there is provided a data processing system including the semiconductor device.

According to the present invention, recess channel transistors having different characteristics can be formed simultaneously. Therefore, when the present invention is applied to a DRAM, a cell transistor of a memory cell and a transistor of a peripheral circuit can be simultaneously formed in the same process.

### BRIEF DESCRIPTION OF THE DRAWINGS

The above features and advantages of the present invention will be more apparent from the following description of certain preferred embodiments taken in conjunction with the accompanying drawings, in which:

FIGS. 1A to 1E are a configuration of a semiconductor device according to the first embodiment of the present invention;

FIGS. 2A to 2C are schematic perspective view for explaining a shape of the active region in which the transistor is formed;

FIGS. 3A to 3E are process diagrams for explaining the method of manufacturing the semiconductor device, especially process for forming hard mask and etching a semiconductor substrate, according to the first embodiment;

FIGS. 4A to 4E are process diagrams for explaining the method of manufacturing the semiconductor device, especially process for forming sidewall insulating film, according to the first embodiment;

FIGS. 5A to 5E are process diagrams for explaining the method of manufacturing the semiconductor device, especially process for forming photoresist, according to the first embodiment;

FIGS. 6A to 6E are process diagrams for explaining the method of manufacturing the semiconductor device, especially process for etching a semiconductor substrate, according to the first embodiment;

FIGS. 7A to 7E are process diagrams for explaining the method of manufacturing the semiconductor device, especially process for forming sidewall insulating film, according to the first embodiment;

FIGS. 8A to 8E are process diagrams for explaining the method of manufacturing the semiconductor device, especially process for forming photoresist, according to the first embodiment;

FIGS. 9A to 9E are process diagrams for explaining the method of manufacturing the semiconductor device, especially process for etching a semiconductor substrate, according to the first embodiment;

FIGS. 10A to 10E are process diagrams for explaining the method of manufacturing the semiconductor device, especially process for forming element isolation region, according to the first embodiment;

FIGS. 11A to 11E are process diagrams for explaining the method of manufacturing the semiconductor device, especially process for forming photoresist, according to the first embodiment;

FIGS. 12A to 12E are process diagrams for explaining the method of manufacturing the semiconductor device, especially process for forming gate trenches, according to the first embodiment;

FIGS. 13A to 13E are process diagrams for explaining the method of manufacturing the semiconductor device, especially process for forming gate electrodes, according to the first embodiment; and

FIG. 14 is a block diagram showing a configuration of a data processing system using the semiconductor device and shows a case that the semiconductor device is a DRAM.

### DETAILED DESCRIPTION OF THE EMBODIMENTS

Preferred embodiments of the present invention will be explained below in detail with reference to the accompanying drawings.

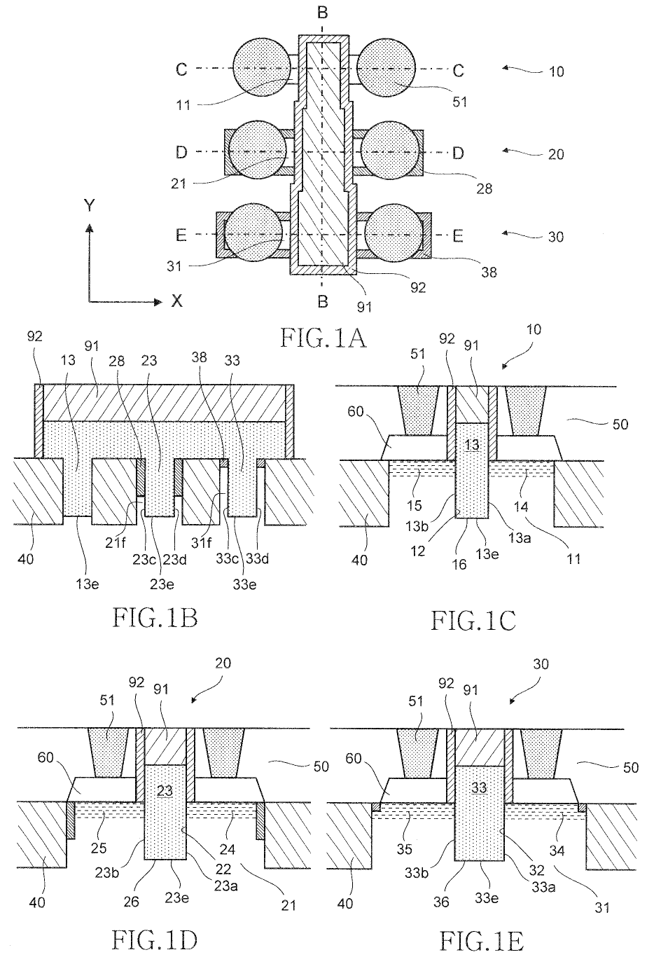

FIGS. 1A to 1E show a configuration of a semiconductor device according to the first embodiment of the present invention, where FIG. 1A is a schematic plan view, FIG. 1B is a schematic cross-sectional view along a line B-B shown in FIG. 1A, FIG. 1C is a schematic cross-sectional view along a line C-C shown in FIG. 1A, FIG. 1D is a schematic cross-sectional view along a line D-D shown in FIG. 1A, and FIG. 1E is a schematic cross-sectional view along a line E-E shown in FIG. 1A.

As shown in FIGS. 1A to 1E, the semiconductor device according to the present embodiment includes three transistors 10, 20, and 30. The transistors 10, 20, and 30 are formed in active regions 11, 21, and 31, respectively. These active regions 11, 21, and 31 are isolated by an element isolation region 40. While not particularly limited, in the present embodiment, the element isolation region 40 has an STI (Shallow Trench Isolation) structure.

The transistors 10, 20, and 30 are all recess channel MOS transistors. Therefore, gate trenches 12, 22, and 32 are formed in the active regions 11, 21, and 31, respectively. While widths of the gate trenches 12, 22, and 32 in an X direction are different from each other in the present embodiment, the present invention is not limited to these different widths.

A part of each of gate electrodes 13, 23, and 33 is embedded into each gate trench. While the gate electrodes 13, 23, and 33 are short-circuited with each other in the present embodiment, the present invention is not limited to the mutual short-circuiting. A gate cap 91 is provided at an upper part of each of the gate electrodes 13, 23, and 33. A sidewall insulating film 92 is provided on side surfaces of the gate electrodes 13, 23, and 33 and the gate cap 91.

As shown in FIG. 1A, planar shapes of the active regions 11, 21, and 31 are approximately rectangular having the X direction as a longitudinal direction. The gate electrodes 13, 23, and 33 are provided along a Y direction to cross center parts of the active regions 11, 21, and 31 that are in the X direction, respectively. Source regions 14, 24, and 34 and drain regions 15, 25, and 35 are provided at a mutually opposite side of the gate electrodes 13, 23, and 33 in the active regions 11, 21, and 31, respectively. The X direction and the Y direction are horizontal to a main surface of a semiconductor substrate, that is, the X and Y directions are in a plane direction of the semiconductor substrate.

The source regions 14, 24, and 34 and the drain regions 15, 25, and 35 are connected to upper layer wirings (not shown) via through-hole electrodes 51 piercing through an interlayer insulating film 50. While not particularly limited, in the present embodiment, an epitaxial layer 60 is formed on upper surfaces of the source regions 14, 24, and 34 and the drain regions 15, 25, and 35. The through-hole electrodes 51 are provided in contact with the epitaxial layer 60.

The configuration of the semiconductor device according to the present embodiment is explained below for each of the transistors 10, 20, and 30 in this order.

The transistor 10 is explained first.

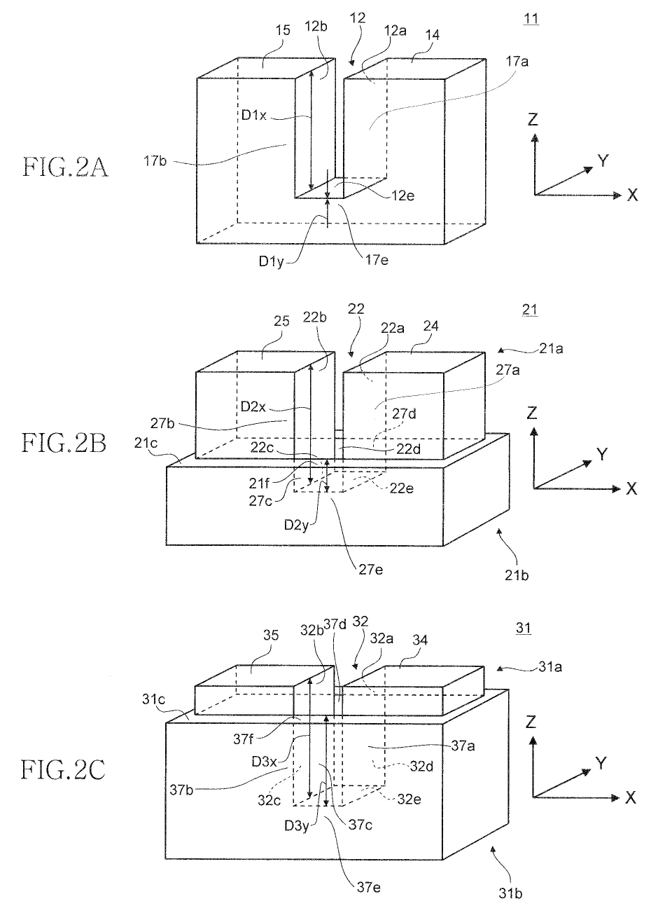

FIG. 2A is a schematic perspective view for explaining a shape of the active region 11 in which the transistor 10 is formed. As shown in FIG. 2A, the gate trench 12 extended to the Y direction is formed in the active region 11, thereby dividing an upper part of the active region 11 into two in the X direction. One of the divided upper parts of the active region 11 is the source region 14, and the other part is the drain region 15.

A depth of the gate trench 12 in a Z direction is expressed as D1x>D1y≅0, where D1x represents a depth of a cross section along the X direction (that is, a height of a YZ plane), and D1y represents a depth of the cross section along the Y direction (that is, a height of an XZ plane). “Depth of a gate trench” means a height of a stage formed in the active region. As shown in FIG. 2A, in the transistor 10, no active region is present in the Y direction of the gate trench 12. That is, because an XZ plane is not present in the gate trench 12, the depth D1y becomes zero. The Z direction is a direction perpendicular to a main surface of the semiconductor substrate, that is, a depth direction of the semiconductor substrate.

Based on this configuration, side surfaces 12a and 12b and a bottom surface 12c are formed for the gate trench 12. The side surfaces 12a and 12b have YZ planes, and the source region 14 and the drain region 15 are formed at an upper part of the plane. Channel regions 17a and 17b are formed at a lower part of the side surfaces 12a and 12b. The bottom surface 12e has an XY plane, and is formed with a channel region 17e. In the transistor 10, a boundary between source/drain regions and the channel region, that is, a depth of a PN junction surface, is near an intermediate point between the upper surface of the active region 11 and the bottom surface 12e of the gate trench 12.

As shown in FIGS. 1A to 1E, a part of the gate electrode 13 is embedded into the gate trench 12 via a gate insulating film 16. Therefore, the source region 14 is provided at a position facing a side surface 13a of the gate electrode 13 via the gate insulating film 16. Similarly, the drain region 15 is provided at a position facing a side surface 13b of the gate electrode 13 via the gate insulating film 16. The side surfaces 13a and 13b of the gate electrode 13 are both YZ planes, and correspond to the side surfaces 12a and 12b of the gate trench 12. Therefore, heights of the side surfaces 13a and 13b of the gate electrode 13 facing the active region 11 are substantially equal to D1x. The heights are “substantially equal” because, in a strict sense, there is a difference between thicknesses of the gate insulating films.

In this configuration, when a voltage exceeding a threshold voltage is applied to the gate electrode 13, the source region 14 and the drain region 15 are electrically connected. That is, in the transistor 10, a current flows in the Z direction in the channel regions 17a and 17b having YZ planes, and a current flows in the X direction in the channel region 17e having an XY plane.

Therefore, a channel width of the transistor 10 is defined by the width W1 in the Y direction of the active region 11. Because a current path formed by the channel regions 17a, 17b, and 17e detours around upper and lower parts of the gate trench 12, a gate length becomes larger than that of the planar transistor. Consequently, a short channel effect is suppressed. As a result, preferably, the transistor 10 is selectively used for a cell transistor included in a memory cell of a DRAM, for example, which is important to suppress a leak current.

The transistor 20 is explained next.

FIG. 2B is a schematic perspective view for explaining a shape of the active region 21 in which the transistor 20 is formed. As shown in FIG. 2B, the active region 21 includes a region 21a having substantially the same configuration as that of the active region 11 constituting the transistor 10, and a region 21b surrounding a lower part of the region 21a. An upper side 21c of the region 21b is positioned above a bottom surface 22e of the gate trench 22. Therefore, a lower part of the gate trench 22 is surrounded by the active region 21 from four directions (the X direction and the Y direction), and an upper part of the gate trench 22 is surround by the active region 21 from two directions (the X direction). In the active region 22, a part surrounding the gate trench 22 from the Y direction constitutes a fin-shaped region 21f.

A depth of the gate trench 22 in the Z direction is expressed as D2x>D2y where D2x represents a depth of a cross section along the X direction (that is, a height of a YZ plane), and D2y represents a depth of the cross section along the Y direction (that is, a height of an XZ plane). The depth D2y of the cross section along the Y direction means a height of the fin-shaped region 21f.

Based on the above configuration, side surfaces 22a to 22d and a bottom surface 22e are formed in the gate trench 22. The side surfaces 22a and 22b have YZ planes. The source region 24 and the drain region 25 are formed at an upper part of the YZ planes. Channel regions 27a and 27b are formed at a lower part of the side surfaces 22a and 22b. The side surfaces 22c and 22d have XZ planes, and are formed with channel regions 27c and 27d. The bottom surface 22e has an XY plane, and is formed with a channel region 27e. In the transistor 20, a boundary between source/drain regions and the channel region, that is, a depth of a PN junction surface, is near an intermediate point between the upper surface of the active region 21 and the upper side 21c of the region 21b.

As shown in FIGS. 1A to 1E, a part of the gate electrode 23 is embedded into the gate trench 22 via a gate insulating film 26. Therefore, the source region 24 is provided at a position facing a side surface 23a of the gate electrode 23 via the gate insulating film 26. Similarly, the drain region 25 is provided at a position facing a side surface 23b of the gate electrode 23 via the gate insulating film 26. Therefore, heights of the side surfaces 23a and 23b of the gate electrode 23 facing the active region 21 are substantially equal to D2x.

Further, lower parts of side surfaces 23c and 23d of the gate electrode 23 face the fin-shaped region 21f via the gate insulating film 26, and upper parts of the side surfaces 23c and 23d of the gate electrode 23 face a sidewall insulating film 28. The side surfaces 23c and 23d of the gate electrode 23 are XZ planes. Therefore, heights of the side surfaces 23c and 23d of the gate electrode 23 facing the active region 21 are substantially equal to D2y. The sidewall insulating film 28 can be configured by a silicon oxide film having an improved film quality, for example.

In this configuration, when a voltage exceeding a threshold voltage is applied to the gate electrode 23, the source region 24 and the drain region 25 are electrically connected. That is, in the transistor 20, a current flows in the Z direction in the channel regions 27a and 27b having YZ planes, and a current flows in the X direction in the channel regions 27c and 27d having YZ planes. A current flows in the X direction in a channel region 27e having an XY plane.

As explained above, the transistor 20 has a larger channel width than that of the transistor 10 by a portion which functions as a channel in the fin-shaped region 21f. Because a current driving capacity is improved, the transistor 20 is preferably used for a transistor requiring a higher current-driving capacity than that of the transistor 10. A threshold voltage of the transistor 20 is slightly lower than that of the transistor 10. Therefore, the transistor 20 can be preferably used for a portion permitted to have a lower threshold voltage than that of the transistor 10 and requiring more on-current than that of the transistor 10 among transistors constituting a peripheral circuit.

Because the transistor 20 has a PN junction surface positioned near an intermediate point between the upper surface of the active region 21 and the upper side 21c of the region 21b, the source/drain regions are not directly in contact with the fin-shaped region 21f. Therefore, a short channel effect does not occur easily in the transistor 20, as is the case with the transistor 10. A threshold voltage can be adjusted by channel concentration at portions not in the fin-shaped region 21f (for example, the side surfaces 22a and 22b of the gate trench 22).

The transistor 30 is explained next.

FIG. 2C is a schematic perspective view for explaining a shape of the active region 41 in which the transistor 30 is formed. As shown in FIG. 2C, the active region 31 includes a region 31a having substantially the same configuration as that of the active region 11 constituting the transistor 10, and a region 31b surrounding a lower part of the region 31a. An upper side 31c of the region 31b is positioned above a bottom surface 32e of the gate trench 32. Therefore, a lower part of the gate trench 32 is surrounded by the active region 31 from four directions (the X direction and the Y direction), and an upper part of the gate trench 32 is surround by the active region 31 from three directions (the X direction). In the active region 32, a part surrounding the gate trench 32 from the Y direction constitutes a fin-shaped region 31f. As explained above, a basic configuration of the active region 31 is the same as the active region 21.

A depth of the gate trench 32 in the Z direction is expressed as D3x>D3y, where D3x represents a depth of a cross section along the X direction (that is, a height of a YZ plane), and D3y represents a depth of the cross section along the Y direction (that is, a height of an XZ plane). The depth D3y of the cross section along the Y direction means a height of the fin-shaped region 31f.

The height of the fin-shaped region 31f is larger than the height of the fin-shaped region 21f in the transistor 20, that is, D3y>D2y.

Based on the above configuration, side surfaces 32a to 32d and the bottom surface 32e are formed in the gate trench 32. The side surfaces 32a and 32b have YZ planes. The source region 34 and the drain region 35 are formed at an upper part of the YZ planes. Channel regions 37a and 37b are formed at a lower part of the side surfaces 32a and 32b. The side surfaces 32c and 32d have XZ planes, and are formed with channel regions 37c and 37d. The bottom surface 32e has an XY plane, and is formed with a channel region 37e. In the transistor 30, a boundary between source/drain regions and the channel region, that is, a depth of a PN junction surface, is near an intermediate point between the upper side 31c of the region 31b and the bottom surface 32e of the gate trench 32.

As shown in FIGS. 1A to 1E, a part of the gate electrode 33 is embedded into the gate trench 32 via a gate insulating film 36. Therefore, the source region 34 is provided at a position facing a side surface 33a of the gate electrode 33 via the gate insulating film 36. Similarly, the drain region 35 is provided at a position facing a side surface 33b of the gate electrode 33 via the gate insulating film 36. Therefore, heights of the side surfaces 33a and 33b of the gate electrode 33 facing the active region 31 are substantially equal to D3x.

Lower parts of side surfaces 33c and 33d of the gate electrode 33 face the fin-shaped region 31f via the gate insulating film 36, and upper parts of the side surfaces 33c and 33d of the gate electrode 33 face a sidewall insulating film 38. The side surfaces 33c and 33d of the gate electrode 33 are XZ planes. Therefore, heights of the side surfaces 33c and 33d of the gate electrode 33 facing the active region 31 are substantially equal to D3y.

The sidewall insulating film 38 is configured by an insulation material of which material or a film quality is different from that of the sidewall insulating film 28 held by the transistor 20. For example, when the sidewall insulating film 28 is made of a silicon oxide film having an improved film quality, a silicon oxide film having a higher etching rate than that of the silicon oxide film having the improved film quality, such as an NSG film or a BPSG (Boro-Phospho Silicate Glass) film, is preferably selected for a material of the sidewall insulating film 38.

In this configuration, when a voltage exceeding a threshold voltage is applied to the gate electrode 33, the source region 34 and the drain region 35 are electrically connected. That is, in the transistor 30, a current flows in the Z direction in the channel regions 37a and 37b having YZ planes, and a current flows in the X direction in the channel regions 37c and 37d having XZ planes. A current flows in the X direction in the channel region 37e having an XY plane.

As explained above, the transistor 30 has a larger channel width than that of the transistor 10 by a portion which functions as a channel in the fin-shaped region 31f. Because the fin-shaped region 31f has a larger height than the fin-shaped region of the transistor 20, the transistor 30 can obtain a higher current-driving capacity than that of the transistor 20. Therefore, the transistor 30 can be preferably used as a transistor requiring a high current-driving capacity among transistors constituting a peripheral circuit.

Because the transistor 30 has a slightly lower threshold voltage than that of the transistor 20, the transistor 30 is preferably used for a portion which is permitted to have a larger off-current than that of the transistor 20 and which requires a larger on-current than that of the transistor 20 among the transistors constituting the peripheral circuit.

Because the transistor 30 has a PN junction surface positioned near an intermediate point between the upper side 31c of the region 31b and the bottom surface 32e of the gate trench 32, the source/drain regions are in contact with the fin-shaped region 31f. Therefore, a short channel effect occurs more easily than in the transistor 20.

Most of the on-current in the transistor 30 flows to the channel regions 37c and 37d. Because the channel regions 37c and 37d are formed in the fin-shaped region 31f, the transistor 30 can be regarded as a fully-depleted transistor. Therefore, adjustment of the threshold voltage based on channel concentration becomes difficult to some extent.

The transistors 10, 20, and 30 are explained above.

The depths D1x, D2x, Dx3 of the cross sections of the gate trenches 12, 22, and 32 along the X direction are equal to each other. Therefore, the gate trenches 12, 22, and 32 are not required to be formed separately, and can be all formed simultaneously. That is, plural types of the transistors 10, 20, and 30 having different configurations can be formed simultaneously.

A method of manufacturing the semiconductor device according to the present embodiment is explained next.

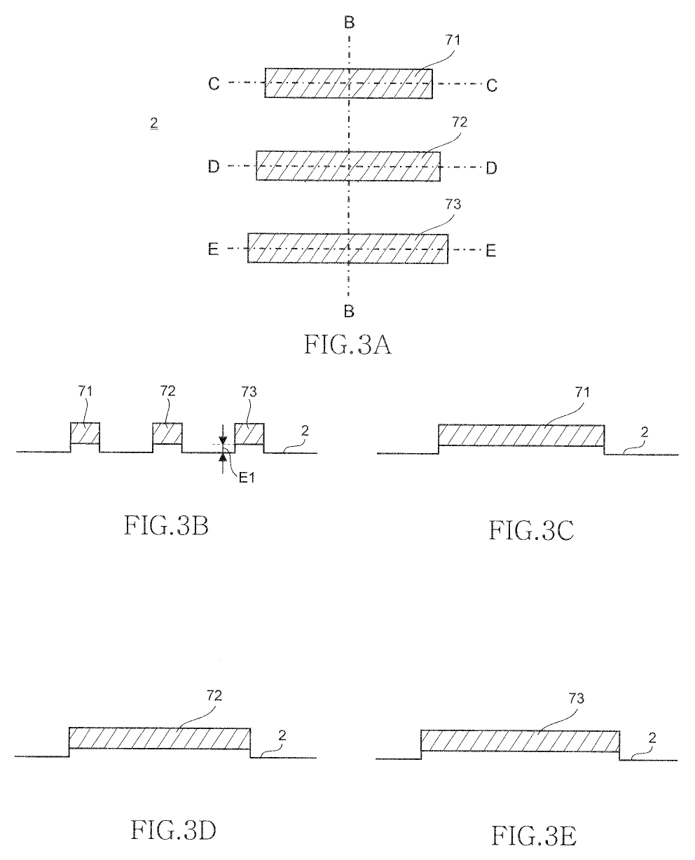

FIGS. 3A to 3E to FIGS. 13A to 13E are process diagrams for explaining the method of manufacturing the semiconductor device according to the present embodiment, where each diagram of “A” is a schematic plan view, each diagram of “B” is a schematic cross-sectional view along the line B-B shown in “A”, each diagram of “C” is a schematic cross-sectional view along the line C-C shown in “A”, each diagram of “D” is a schematic cross-sectional view along the line D-D shown in “A”, and each diagram of “E” is a schematic cross-sectional view along the line E-E shown in “A”.

First, as shown in FIGS. 3A to 3E, a silicon nitride film is formed on the entire surface of a semiconductor substrate 2 by the CVD method. By patterning this silicon nitride film, hard masks 71 to 73 having a thickness of about 100 nm, respectively are formed. The hard masks 71 to 73 are masks for forming the active regions 11, 21, and 31, respectively. The semiconductor substrate 2 is etched by using the hard masks 71 to 73 (a first etching). Preferably, an etching amount E1 is set at 20 nm, for example.

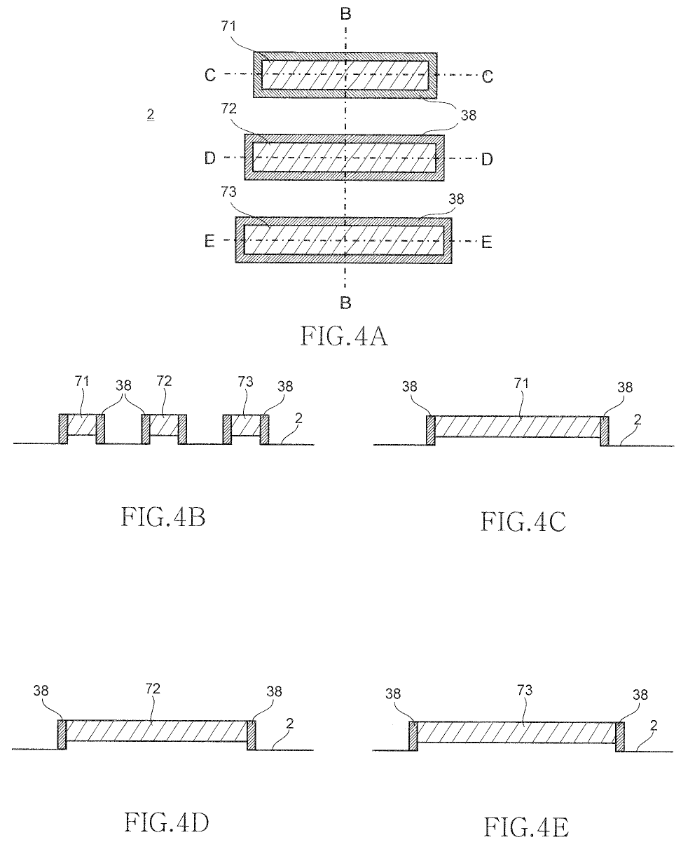

Next, as shown in FIGS. 4A to 4E, a silicon oxide film having a thickness of about 15 nm is formed on the entire surface of the semiconductor substrate 2 by the CVD method. This silicon oxide film is etched back to form the sidewall insulating film 38. Accordingly, side surfaces of the hard masks 71 to 73 and the etched surface of the semiconductor substrate 2 are covered by the sidewall insulating film 38. Consequently, as shown in FIG. 4A, the semiconductor substrate 2 is covered by the hard masks 71 to 73, and is also further covered by a film thickness of the side wall insulating film 38.

The silicon oxide film formed on the entire surface of the semiconductor substrate 2 is preferably an NSG (Nondoped Silicate Glass) film using TEOS (Tetra Ethyl Ortho Silicate), and is preferably reinforced by improving a film quality before performing an etch back. ISSG (In-situ steam generation) oxidation is preferable as a method of improving the film quality. ISSG oxidation is a type of radical oxidation. When ISSG oxidation is performed, a silicon oxide film formed by this oxidation becomes more precise than a silicon oxide film immediately after being formed by the CVD method. Therefore, the sidewall insulating film 38 can obtain higher strength. When ISSG oxidation is performed, the semiconductor substrate 2 itself is not oxidized because the entire surface of the semiconductor substrate 2 is covered by the silicon oxide film.

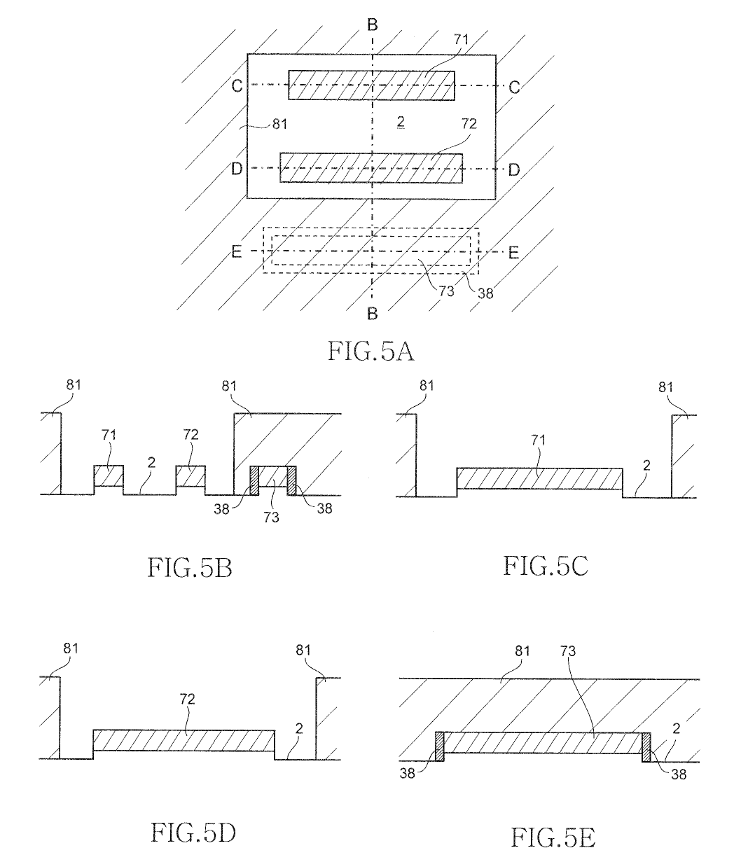

Next, as shown in FIGS. 5A to 5E, the hard masks 71 and 72 are exposed, and a photoresist 81 covering the hard mask 73 is formed. The sidewall insulating film 38 is removed by using this photoresist 81 as a mask. Accordingly, all the sidewall insulating film 38 around the hard masks 71 and 72 is removed, and the sidewall insulating film 38 around the hard mask 73 remains as it is.

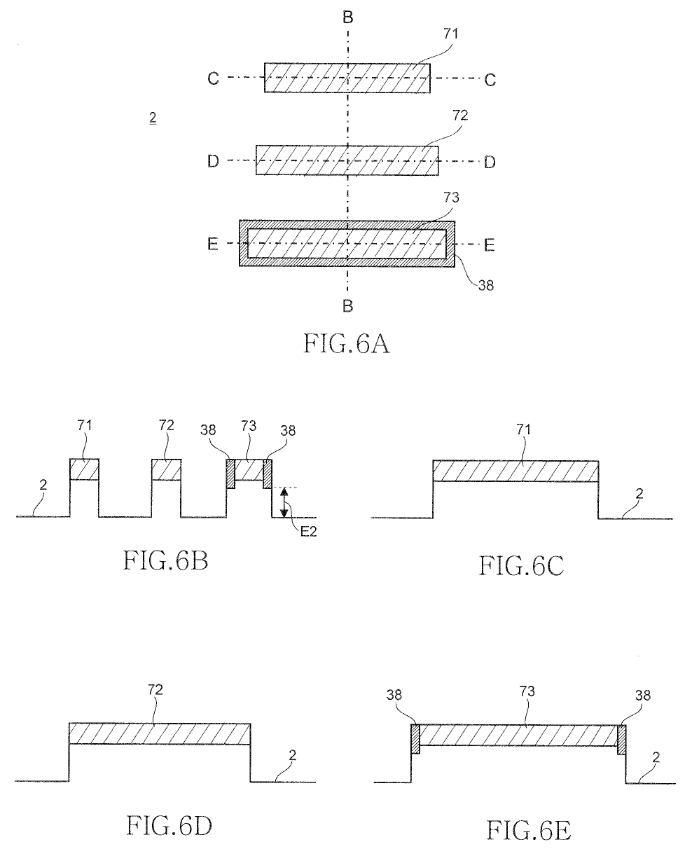

Next, as shown in FIGS. 6A to 6E, the photoresist 81 is removed, and the semiconductor substrate 2 is further etched (a second etching) by using the hard masks 71 to 73 and the sidewall insulating film 38 as masks. Preferably, an etching amount E2 is set at 100 nm, for example. By performing this etching, a height of the semiconductor substrate 2 stretched at lower parts of the hard masks 71 to 73 becomes E1+E2, and a height of the semiconductor substrate 2 stretched at a lower part of the sidewall insulating film 38 becomes E2.

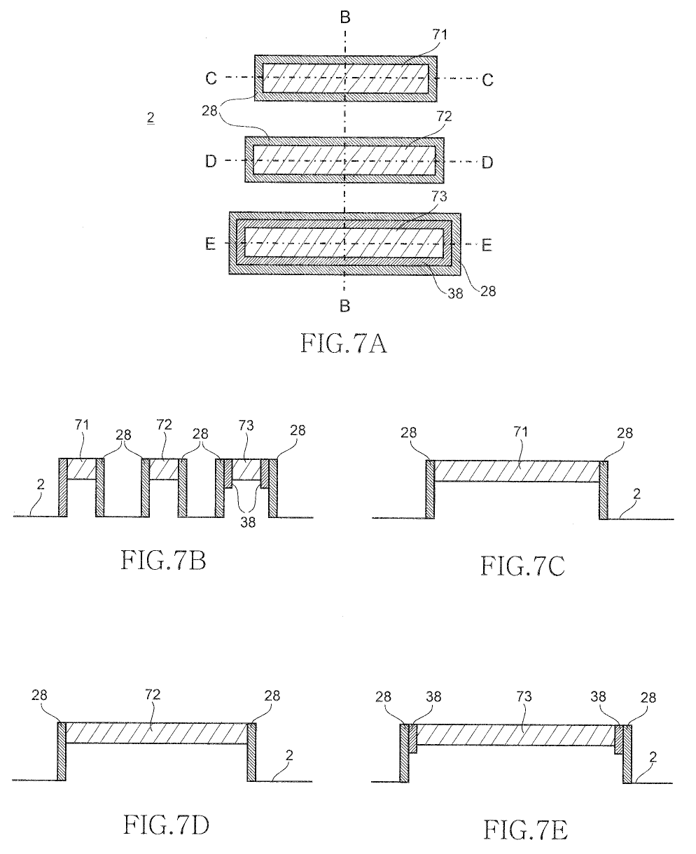

Next, as shown in FIGS. 7A to 7E, a silicon oxide film having a thickness of about 15 nm is formed on the entire surface of the semiconductor substrate 2 by the CVD method. This silicon oxide film is etched back to form the sidewall insulating film 28. An NSG film or a BPSG film is preferably used for a material of the sidewall insulating film 28. Accordingly, side surfaces of the hard masks 71 and 72, the etched surface of the semiconductor substrate 2, and a side surface of the sidewall insulating film 38 are covered by the sidewall insulating film 28. Consequently, as shown in FIG. 7A, the semiconductor substrate 2 is covered by the hard masks 71 to 73, and is also further covered by film thicknesses of the side wall insulating films 28 and 38.

The silicon oxide film constituting the sidewall insulating film 28 is not reinforced by improving the film quality. Accordingly, the side surface of the hard mask 73 is covered by two types of the sidewall insulating films 28 and 38 having different film qualities.

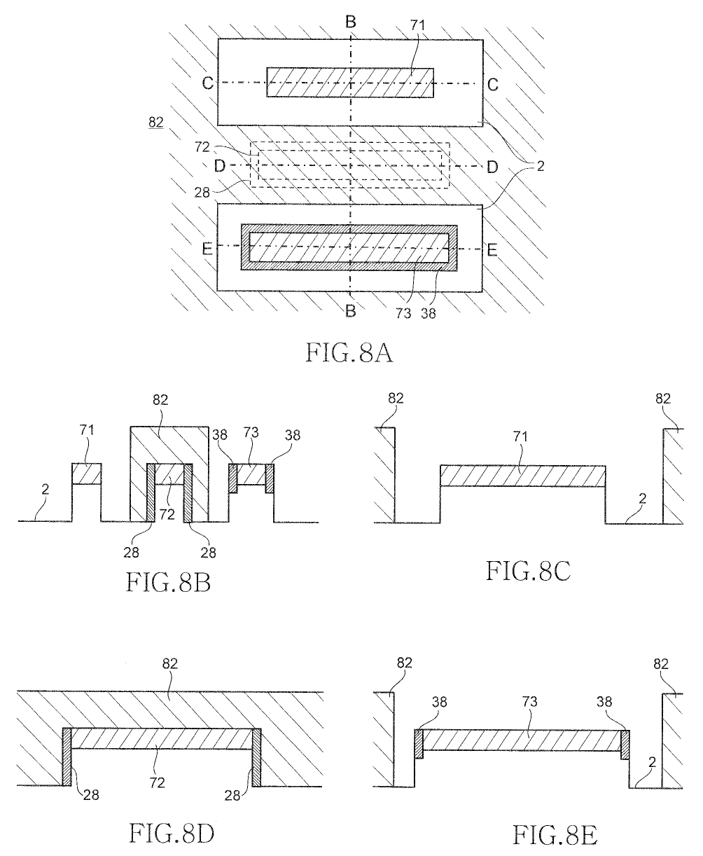

Next, as shown in FIGS. 8A to 8E, the hard masks 71 and 73 are exposed, and the photoresist 82 covering the hard mask 72 is formed. The sidewall insulating film 28 is removed by using this photoresist 82 as a mask. Accordingly, the sidewall insulating film 28 around the hard masks 71 and 73 is all removed. On the other hand, the sidewall insulating film 28 around the hard mask 72 remains as it is.

Because both the sidewall insulating film 28 and the sidewall insulating film 38 are made of silicon oxide films, the sidewall insulating film 38 is also exposed to an etching environment when etching the sidewall insulating film 28. However, as explained above, a film quality of the sidewall insulating film 38 is improved by ISSG oxidation, and a film quality of the sidewall insulating film 28 is not improved. Therefore, although both sidewall insulating films are made of silicon oxide films, an etching rate of about ten times can be secured. Consequently, the sidewall insulating film 28 can be selectively removed without substantially removing the sidewall insulating film 38.

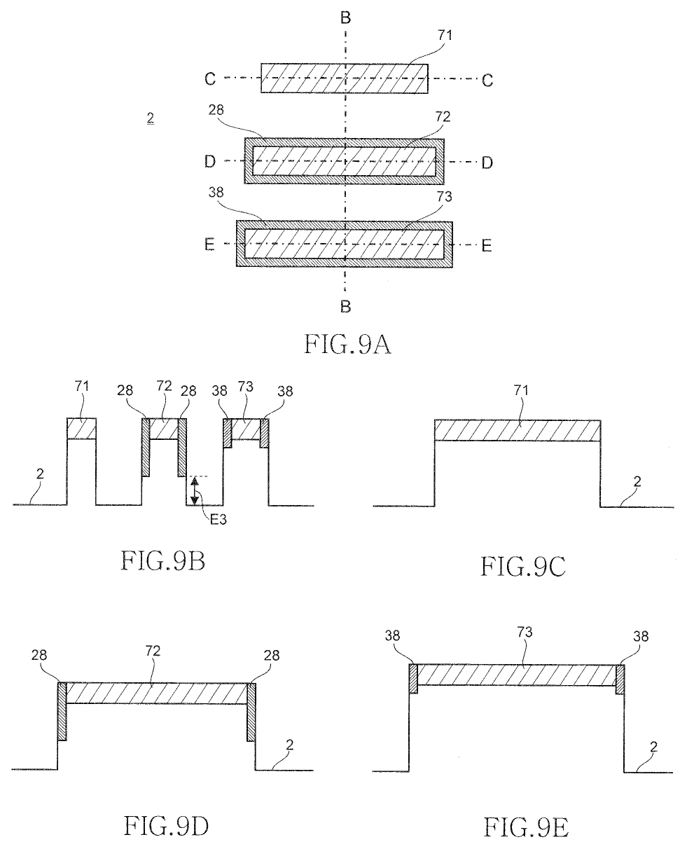

Next, as shown in FIGS. 9A to 9E, the photoresist 82 is removed, and the semiconductor substrate 2 is further etched (a third etching) by using the hard masks 71 to 73 and the sidewall insulating films 28 and 38 as masks. Preferably, an etching amount E3 is set at 100 nm, for example. By performing this etching, the active regions 11, 21, and 31 are completed. A height of the active region 11 is E1+E2+E3. A height of the active region 21 is E1+E2+E3 at a lower part of the hard mask 72, and is E3 at a lower part of the sidewall insulating film 28. Further, a height of the active region 31 is E1+E2+E3 at a lower part of the hard mask 73, and is E2+E3 at a lower part of the sidewall insulating film 38.

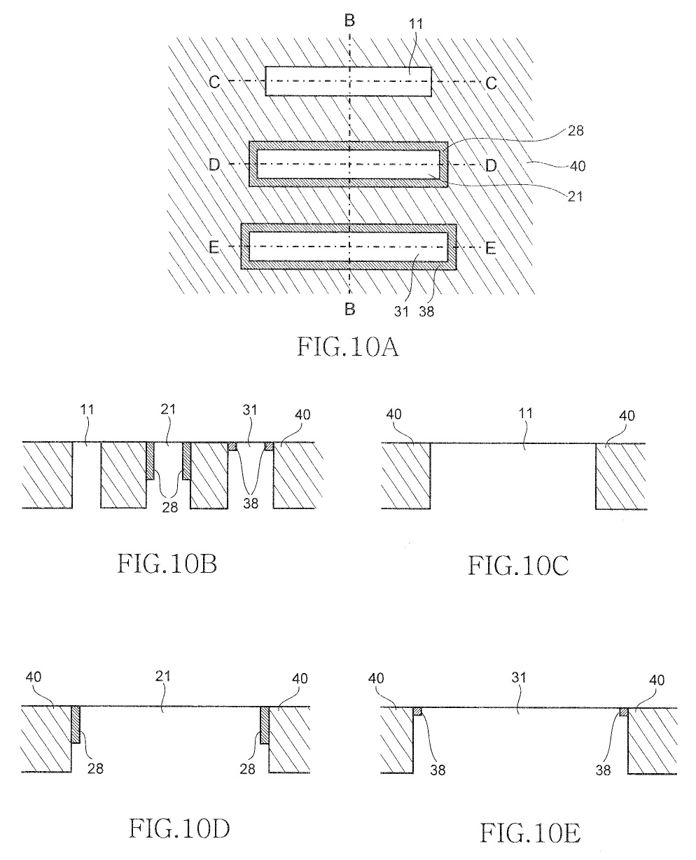

Next, as shown in FIGS. 10A to 10E, the hard masks 71 to 73 are removed, and a silicon oxide film is embedded into trenches formed on the semiconductor substrate 2. Further, the embedded silicon oxide film is polished by the CMP by using the semiconductor substrate 2 as a stopper, thereby forming the element isolation region 40. In this case, upper parts of the sidewall insulating films 28 and 38, more specifically, parts provided in contact with the side surfaces of the hard masks 72 and 73, are also removed and flatted.

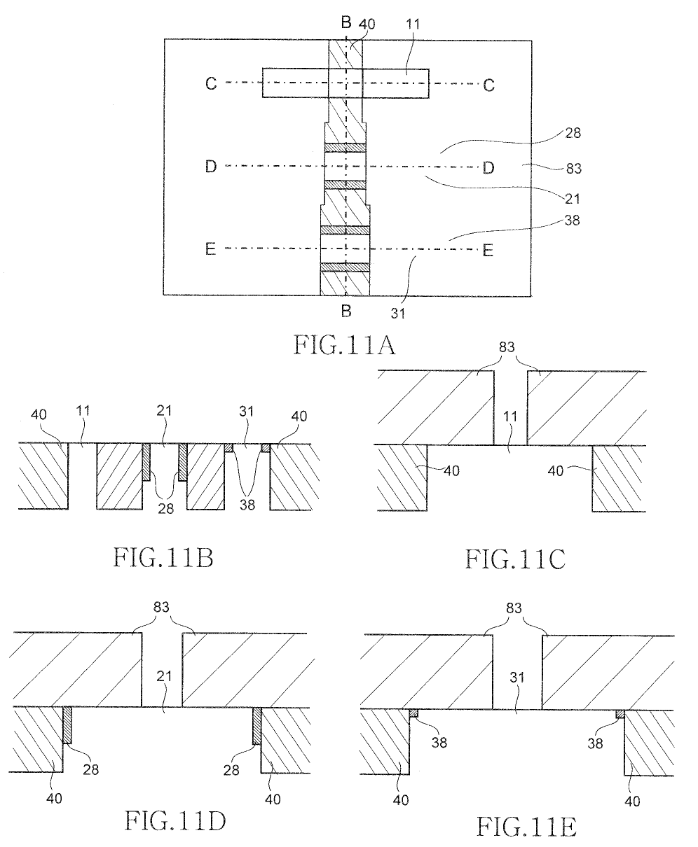

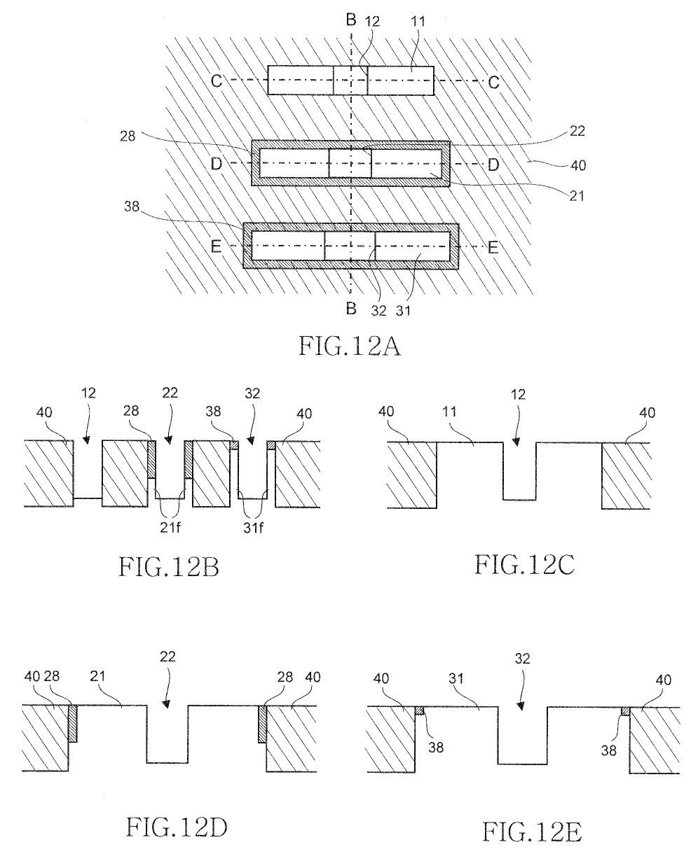

Next, as shown in FIGS. 11A to 11E, in the active regions 11, 21, and 31, center parts at which gate trenches are to be formed are exposed, and a photoresist 83 covering other parts is formed. The semiconductor substrate 2 is etched by using the photoresist 83 as a mask, thereby simultaneously forming the gate trenches 12, 22, and 32, as shown in FIGS. 12A to 12E. Depths of the gate trenches 12, 22, and 32 are set larger than a depth of a bottom of the sidewall insulating film 28, and are also shorter than a depth of a bottom of the element isolation region 40.

Accordingly, as shown in FIGS. 12A to 12E, the fin-shaped region 21f having a relatively a small height is formed in the active region 21, and the fin-shaped region 31f having a relatively large height is formed in the active region 31. No fin-shaped region is formed in the active region 11. After the fin-shaped regions 21f and 31f are formed, a channel doping is performed when necessary. However, because the fin-shaped regions 21f and 31f are perpendicular to the semiconductor substrate 2, ion implantation into the semiconductor substrate 2 needs to be performed from an inclined direction.

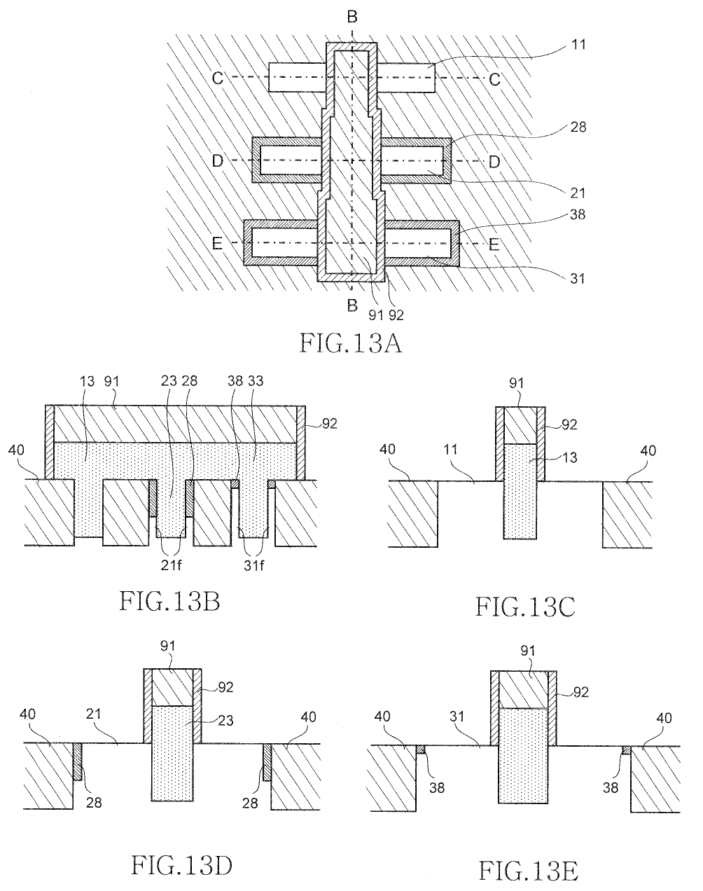

Next, as shown in FIGS. 13A to 13C, a conductive film becoming a material of a gate electrode is formed on the entire surface of the semiconductor substrate 2 so that the gate trenches 12, 22, and 32 are filled completely. A silicon nitride film is further formed at an upper part of the conductive film. The silicon nitride film is patterned to form the gate cap 91, and the conductive film is patterned by using this gate cap as a mask, thereby forming the gate electrodes 13, 23, and 33. Accordingly, the gate electrodes 13, 23, and 33 having parts thereof embedded in the gate trenches 12, 22, and 32, respectively are formed.

Thereafter, a silicon nitride film is formed on the entire surface, and this silicon nitride film is etched back to form the sidewall insulating film 92 on side surfaces of the gate electrodes 13, 23, and 33 and the gate gap. Further, a dopant is ion implanted into the semiconductor substrate 2, thereby forming the source region 14 and the drain region as shown in FIGS. 1A to 1E.

Thereafter, the epitaxial layer 60 is formed, and the entire surface is covered by the interlayer insulating film 50. Through-holes to expose a part of the epitaxial layer 60 are formed in the interlayer insulating film 50, and a conductive film is embedded into the through-holes, thereby forming the through-hole electrodes 51. The semiconductor device according to the present embodiment is thus completed.

As explained above, according to the manufacturing method of the present embodiment, the gate trenches 12, 22, and 32 are formed simultaneously in the same process. Therefore, the transistors 10, 20, and 30 having different channel configurations are not required to be separately formed, and can be formed simultaneously.

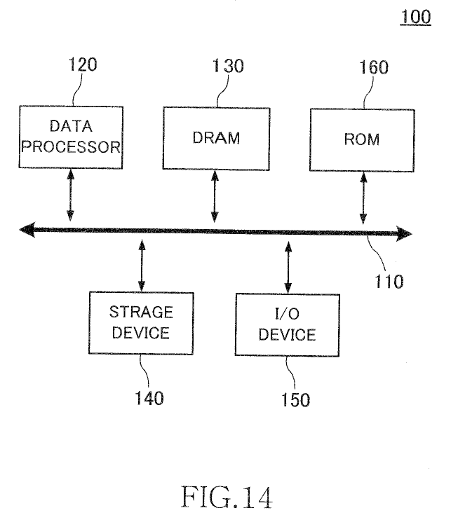

FIG. 14 is a block diagram showing a configuration of a data processing system 100 using the semiconductor device and shows a case that the semiconductor device is a DRAM.

The data processing system 100 shown in FIG. 14 has a configuration such that a data processor 120 and a semiconductor device (DRAM) 130 according to the present embodiment are mutually connected via a system bus 110. Examples of the data processor 120 include, but are not limited to, a microprocessor (MPU) and a digital signal processor (DSP). In FIG. 14, for the sake of simplification, the data processor 120 and the DRAM 130 are connected via the system bus 110. However, these components can be connected by a local bus rather than being connected via the system bus 110.

In FIG. 14, for the sake of simplification, only one set of system bus 110 is shown. However, the system buses 110 can be arranged via a connector or the like in series or in parallel according to need. In the memory-system data processing system shown in FIG. 14, while a storage device 140, an I/O device 150, and a ROM 160 are connected to the system bus 110, these are not necessarily essential constituent elements.

Examples of the storage device 140 include a hard disk drive, an optical disk drive, and a flash memory. Examples of the I/O device 150 include a display device such as a liquid crystal display, and an input device such as a keyboard and a mouse. Regarding the I/O device 150, it is only necessary to provide either one of the input device or the output device. Further, for the sake of simplicity, each constituent element shown in FIG. 14 is shown one each. However, the number is not limited to one, and a plurality of one or two or more constituent elements can be provided.

It is apparent that the present invention is not limited to the above embodiments, but may be modified and changed without departing from the scope and spirit of the invention.

For example, in the above embodiment, while simultaneous formation of three types of recess channel transistors having different channel configurations is explained, the present invention is not limited thereto. At least two types of recess channel transistors can be formed simultaneously. When forming two types of recess channel transistors, fin-shaped regions can be provided in both transistors (the transistors 20 and 30, for example), or a fin-shaped region can be provided in one transistor (the transistors 20, for example) without providing a fin-shaped region in the other transistor (the transistor 10, for example).

In the above embodiment, longitudinal directions of the active regions 11, 21, and 31 constituting the transistors 10, 20, and 30 are the X direction, and extended directions of the gate electrodes 13, 23, and 33 are the Y direction. However, directions of these transistors can be different from each other. For example, for the transistor 10, a longitudinal direction of the active region 11 can be the X direction, and an extended direction of the gate electrode 13 can be the Y direction. For the transistor 20, a longitudinal direction of the active region 21 can be the Y direction, and an extended direction of the gate electrode 23 can be the XY direction.

While the present invention is preferably applied to a DRAM, the application of the present invention is not limited thereto, and the present invention can be also applied to other semiconductor devices such as semiconductor memories other than a DRAM or logic LSIs such as a processor.

What is claimed is:

1. A semiconductor device comprising a plurality of transistors including at least first and second transistors, wherein
each of the transistors includes an active region having a gate trench formed therein, a gate electrode provided a long a first direction crossing the active region in which at least a part of the gate electrode is embedded in the gate trench, and a source region and a drain region provided in the active region and arranged side by side in a second direction intersecting with the first direction with intervention of the gate electrode,
a depth of the gate trench in a cross section along the first direction in the first transistor is different from a depth of the gate trench in a cross section along the first direction in the second transistor, and
a depth of the gate trench in a cross section along the second direction in the first transistor is substantially equal to a depth of the gate trench in a cross section along the second direction in the second transistor.

2. The semiconductor device as claimed in claim 1, wherein, in each of the transistors, the depth of the gate trench in the cross section along the second direction is larger than the depth of the gate trench in the cross section along the first direction.

3. The semiconductor device as claimed in claim 1, wherein, in one of the first and second transistors, the depth of the gate trench in the cross section along the first direction is substantially zero.

4. The semiconductor device as claimed in claim 3, wherein the one of the first and second transistors is a transistor included in a memory cell, and the other one of the first and second transistors is a transistor included in a peripheral circuit.

5. The semiconductor device as claimed in claim 1, wherein the gate electrode of the first transistor is short-circuited with the gate electrode of the second transistor.

6. The semiconductor device as claimed in claim 1, wherein the transistors further include a third transistor,
depths of the gate trenches in the cross sections along the first direction in the first to third transistors are mutually different from one another, and
depths of the gate trenches in the cross sections along the second direction in the first to third transistors are mutually substantially equal to one another.

7. A semiconductor device comprising a plurality of transistors including at least first and second transistors, wherein each of the transistors includes:
an active region having a gate trench formed therein;
a gate electrode embedded in the gate trench via a gate insulating film, and having first and second side surfaces perpendicular to a main surface of a semiconductor substrate and parallel to each other, third and fourth side surfaces perpendicular to a main surface of the semiconductor substrate and parallel to each other, and a bottom surface parallel to the main surface of the semiconductor substrate;
a source region provided in the active region, and provided at a position facing the first side surface of the gate electrode via the gate insulating film;
a drain region provided in the active region, and provided at a position facing the second side surface of the gate electrode via the gate insulating film;
a first channel region provided in the active region, and provided at a position facing at least the bottom surface of the gate electrode via the gate insulating film; and
a second channel region provided in the active region, and provided at a position facing the third and fourth side surfaces of the gate electrode via the gate insulating film, wherein
heights of the first and second side surfaces of the gate electrode at a part facing the active region in the first transistor are substantially equal to heights of the first and second side surfaces of the gate electrode at a part facing the active region in the second transistor, and
heights of the third and fourth side surfaces of the gate electrode at a part facing the active region in the first transistor are different from heights of the third and fourth side surfaces of the gate electrode at a part facing the active region in the second transistor.

8. The semiconductor device as claimed in claim 7, wherein the third and fourth side surfaces of the gate electrode at a part not facing the active region face a sidewall insulating film, and at least one of a material and a film quality of the sidewall insulating film in the first transistor is different from a material and a film quality of the sidewall insulating film in the second transistor.

9. A method of manufacturing a semiconductor device comprising:
forming first and second hard masks on a semiconductor substrate;
etching the semiconductor substrate by using the first and second hard masks;
forming a first sidewall insulating film on side surfaces of the first and second hard masks, respectively;
selectively removing the first sidewall insulating film formed on the side surface of the first hard mask;
etching the semiconductor substrate by using the first and second hard masks and the first sidewall insulating film;
removing the first and second hard masks, and thereafter simultaneously forming first and second gate trenches, respectively on a part of the semiconductor substrate at removed portions of the first and second hard masks;
forming first and second gate electrodes by embedding a conductive material into the first and second gate trenches; and
forming a source region and a drain region on the semiconductor substrate positioned at a mutually different side viewed from the first and second gate electrodes, respectively.

10. The method of manufacturing the semiconductor device as claimed in claim 9, further comprising, after a second etching and before forming the gate trenches,
forming a second sidewall insulating film on the side surface of the first hard mask and on a side surface of the first sidewall insulating film, respectively;
selectively removing the second sidewall insulating film formed on the side surface of the second hard mask; and
etching the semiconductor substrate by using the first and second hard masks and the first and second sidewall insulating films.

11. The method of manufacturing the semiconductor device as claimed in claim 10, wherein at least one of a material and a film quality of the first sidewall insulating film is different from a material and a film quality of the second sidewall insulating film.

12. The method of manufacturing a semiconductor device as claimed in claim 11, wherein forming the first sidewall insulating film includes forming a silicon oxide film on an entire surface, improving a film quality of the silicon oxide film, and etching back the silicon oxide film of which film quality is improved.

13. The method of manufacturing a semiconductor device as claimed in claim 12, wherein improving the film quality is performed by ISSG (In-situ steam generation) oxidation on the silicon oxide film.

14. A date processing system comprising a semiconductor device having a plurality of transistors including at least first and second transistors, wherein
each of the transistors includes an active region having a gate trench formed therein, a gate electrode provided along a first direction crossing the active region in which at least a part of the gate electrode is embedded in the gate trench, and a source region and a drain region provided in the active region and arranged side by side in a second direction intersecting with the first direction with intervention of the gate electrode,
a depth of the gate trench in a cross section along the first direction in the first transistor is different from a depth of the gate trench in a cross section along the first direction in the second transistor, and
a depth of the gate trench in a cross section along the second direction in the first transistor is substantially equal to a depth of the gate trench in a cross section along the second direction in the second transistor.
